(19) United States
(12) Patent Application Publication
(10) Pub. No.: US 2025/0351467 A1
(43) Pub. Date: Nov. 13, 2025

(54) SEMICONDUCTOR DEVICE AND METHOD OF FORMING THE SAME

(71) Applicant: MICRON TECHNOLOGY, INC., Boise, ID (US)

(72) Inventor: Toshihiko Miyashita, Higashihiroshima-shi (JP)

(73) Assignee: MICRON TECHNOLOGY, INC., Boise, ID (US)

(21) Appl. No.: 19/190,028

(22) Filed: Apr. 25, 2025

Related U.S. Application Data
(60) Provisional application No. 63/646,545, filed on May 13, 2024.

(51) Int. Cl. H10D 30/69; H01L 21/3115; H10D 30/01; H10D 62/832; H10D 84/85

(52) U.S. Cl. CPC H10D 30/792; H01L 21/31155; H10D 30/027; H10D 62/832; H10D 84/856

(57) ABSTRACT

An example apparatus includes a substrate; a first region on the substrate; a second region on the substrate different from the first region; at least one first transistor provided in the first region; at least one second transistor provided in the second region different from the first transistor; a first stress film covering over the first transistor; and a second stress film covering over the second transistor; wherein stress of the first stress film is different from stress of the second stress film.

### CROSS-REFERENCE TO RELATED APPLICATIONS

This application claims the filing benefit of U.S. Provisional Application No. 63/646,545, filed May 13, 2024. This application is incorporated by reference herein in its entirety and for all purposes.

### BACKGROUND

An electronic circuit contained in a semiconductor device includes many transistors. The operating speed of transistors are increased by improving the mobility of the transistors. When the operating speed of the transistors is increased, the operating speed of an electronic circuit including the transistors is also increased, thereby improving the capability of a semiconductor device.

### BRIEF DESCRIPTION OF THE DRAWINGS

FIG. 1A is a vertically cross-sectional view showing a schematic configuration of a part of a first peripheral region of a semiconductor device according to an embodiment. FIG. 1B is a vertically cross-sectional view showing a schematic configuration of a part of a second peripheral region of the semiconductor device according to the embodiment. Further, FIGS. 1A and 1B are diagrams showing a schematic configuration at an exemplary process stage following FIGS. 10A and 10B. FIG. 1C is a vertically cross-sectional view showing a schematic configuration including the first peripheral region and the second peripheral region of the semiconductor device according to the embodiment.

FIGS. 2A and 2B to FIGS. 10A and 10B are vertically cross-sectional views showing the semiconductor device according to the embodiment and a method for manufacturing the same, and are diagrams showing an example of a schematic configuration in an exemplary process stage in the order of steps. FIGS. 2A, 3A, 4A, 5A, 6A, 7A, 8A, 9A and 10A are diagrams showing the schematic configuration in the first peripheral region, and FIGS. 2B, 3B, 4B, 5B, 6B, 7B, 8B, 9B and 10B are diagrams showing the schematic configuration in the second peripheral region.

FIG. 11 is a table showing stress values of stress films included in the semiconductor device according to the embodiment.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

A semiconductor device 1 according to an embodiment and a method for manufacturing the same will be hereunder described with reference to the drawings. The semiconductor device 1 will be described while illustrating a dynamic random access memory (DRAM) as an example. In the description of the embodiment, common or related elements, or substantially the same elements are denoted by the same or similar reference signs, and the description thereof will be omitted. In the figures, the dimensions and dimension ratios of respective components in the figures do not necessarily match the dimensions and dimension ratios in the embodiment. The dimensions and dimension ratios of the respective components in plan view and vertically cross-sectional view do not necessarily match with one another. The up-and-down direction in the following description means an up-and-down direction when a semiconductor substrate 10 is located on the lower side.

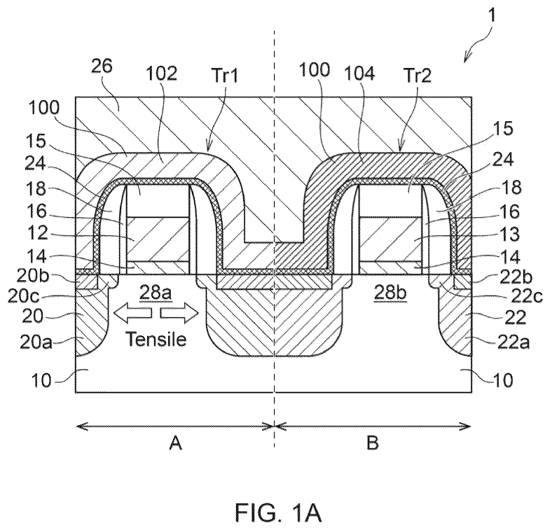

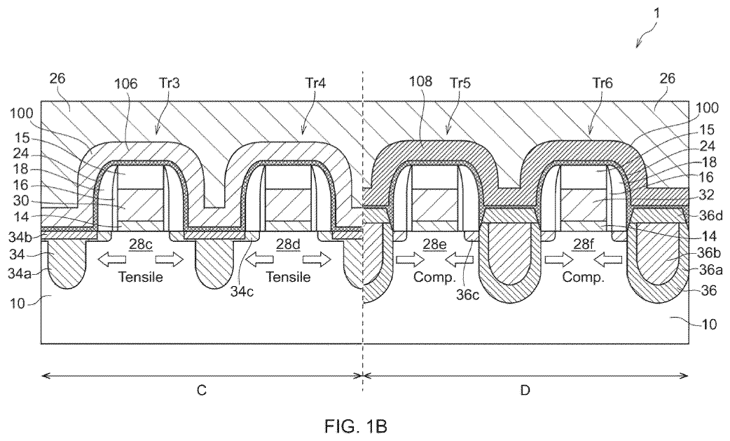

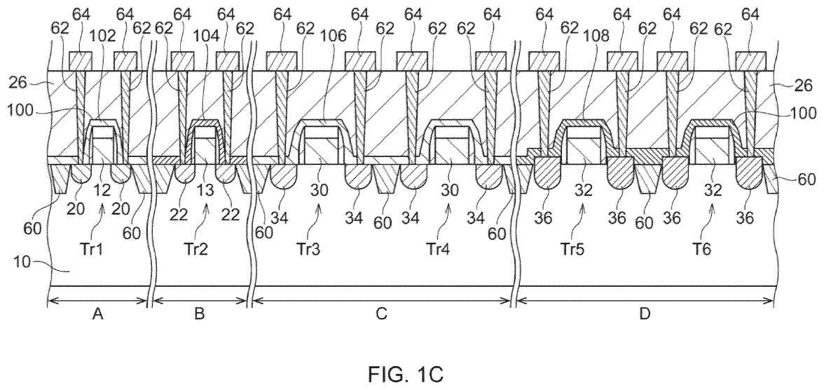

FIG. 1A, FIG. 1B, and FIG. 1C are vertically cross-sectional views showing a schematic configuration of a semiconductor device 1 according to an embodiment. FIG. 1A shows transistors Tr1 and Tr2 arranged in a first peripheral region on a semiconductor substrate 10. The first peripheral region is, for example, a region where a sense amplifier of DRAM is provided. Since the arrangement of the sense amplifier depends on the device dimension of a memory cell region of DRAM, the sizes of the transistors Tr1 and Tr2 provided in the sense amplifier and the distance between the transistors are smaller than those of transistors Tr3 and Tr4 in a second peripheral region described later.

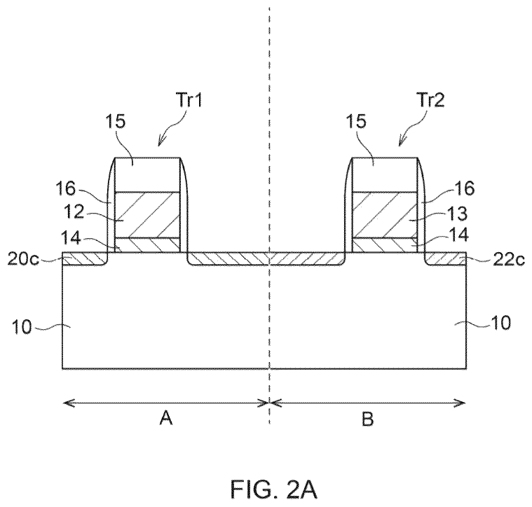

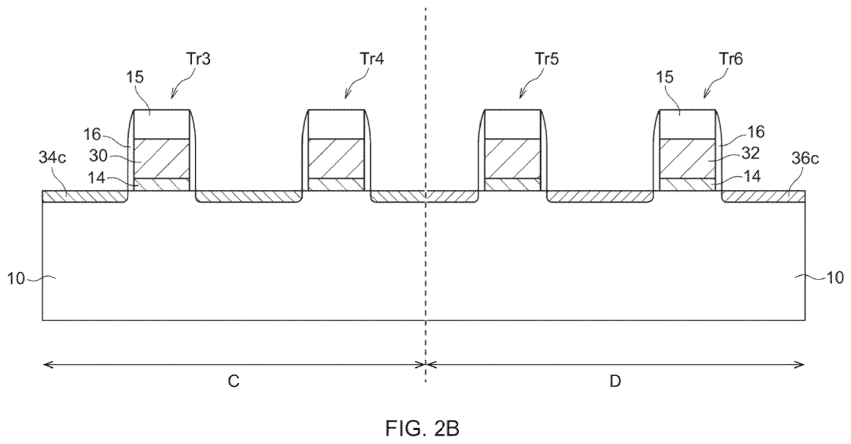

One or two transistors are shown in a first region A, a second region B, a third region C, and a fourth region D shown in FIG. 1A and FIG. 1B. However, this is a typical example, and actually, many transistors are arranged in each region. In FIG. 1A, the first region A and the second region B are shown to be adjacent to each other across a boundary line, but they are actually arranged at separate locations. In FIG. 2A, the third region C and the fourth region D are shown to be adjacent to each other across a boundary line, but they are actually arranged at separate locations. The same applies to FIGS. 2A and 2B to FIGS. 10A and 10B described later.

As shown in FIG. 1A, the first region A and the second region B are provided on the semiconductor substrate 10 in the first peripheral region. The transistor Tr1 is provided in the first region A. The transistor Tr2 is provided in the second region B. The semiconductor substrate 10 in the first region A is doped with, for example, boron (B) to be provided with a P-type conductivity type P-well. The semiconductor substrate 10 in the second region B is doped with, for example, phosphorus (P) to be provided with an N-type conductivity type N-well. The transistor Tr1 is, for example, an N-type conductivity type N-channel metal-oxide-semiconductor field-effect transistor (MOSFET) to be used in a sense amplifier, and the transistor Tr2 is, for example, a P-type conductivity type P-channel MOSFET to be used in a sense amplifier. The transistor Tr1 and the transistor Tr2 include, for example, a complementary metal oxide semiconductor (COM S) circuit.

The transistor Tr1 includes a first gate electrode 12 and sources/drains 20 arranged on the semiconductor substrate 10 on both sides of the first gate electrode 12. The semiconductor substrate 10 below the first gate electrode 12 serves as a channel portion 28a. A gate insulating film 14 is provided between the first gate electrode 12 and the semiconductor substrate 10. A gate upper insulating film 15 is provided on the first gate electrode 12. A first sidewall portion 16 and a second sidewall portion 18 are provided on the sidewalls of the first gate electrode 12 and the gate upper insulating film 15.

The semiconductor substrate 10 includes, for example, a silicon single crystal substrate. The first gate electrode 12 includes a conductive material, and includes, for example, a laminated film of tungsten (W) and polysilicon (Poly-Si). The source/drain 20 includes a doped portion 20a, a silicide portion 20b, and a lightly doped drain (LDD) portion 20c. The doped portion 20a and the LDD portion 20c are doped with impurities such as arsenic (As) or phosphorus (P). The LDD portion 20c is a doped region which is formed shallowly up to a gate end near the surface of the semiconductor substrate 10, and serves as an extension portion of the source/drain 20. The silicide portion 20b includes metal silicide such as nickel platinum silicide (NiPtSi), titanium silicide (TiSi), or cobalt silicide (CoSi). The channel portion 28a is doped with impurities such as phosphorus, arsenic, or boron (B). The gate insulating film 14 includes, for example, a high-K film such as hafnium oxide (HfOx). The High-K film is a general term for insulating materials that have a higher relative dielectric constant than silicon dioxide (SiO₂), and a HfO₂-based film and a La₂O₃-based film are illustrated as examples. The gate upper insulating film 15, the first sidewall portion 16, and the second sidewall portion 18 include silicon nitride (SiN), for example.

The transistor Tr2 includes a second gate electrode 13 and sources/drains 22 arranged on the semiconductor substrate 10 on both sides of the second gate electrode 13. The semiconductor substrate 10 below the second gate electrode 13 serves as a channel portion 28b. A gate insulating film 14 is provided between the second gate electrode 13 and the semiconductor substrate 10. A gate upper insulating film 15 is provided on the second gate electrode 13. A first sidewall portion 16 and a second sidewall portion 18 are provided on the sidewalls of the second gate electrode 13 and the gate upper insulating film 15.

The second gate electrode 13 includes a conductive material, and includes, for example, a laminated film of tungsten (W) and polysilicon (Poly-Si). The source/drain 22 includes a doped portion 22a, a silicide portion 22b, and an LDD portion 22c. The doped portion 22a and the LDD portion 22c are doped with impurities such as boron (B). The LDD portion 22c is a doped region which is formed shallowly up to a gate end near the surface of the semiconductor substrate 10, and serves as an extension portion of the source/drain 22. The silicide portion 22b includes metal silicide such as nickel platinum silicide (NiPtSi), titanium silicide (TiSi), or cobalt silicide (CoSi). The channel portion 28b is doped with impurities such as phosphorus, arsenic, or boron (B). The other configurations are the same as the transistor Tr1.

A first insulating film 24 and a stress layer 100 are provided at the upper portions of the transistors Tr1 and Tr2 and on the semiconductor substrate 10 so as to cover them. An interlayer insulating film 26 is provided on the stress layer 100 so as to cover it. The stress layer 100 includes a first stress film 102 and a second stress film 104. The first stress film 102 is provided in the first region A. The second stress film 104 is provided in the second region B. As described later, a damage is applied to the second stress film 104, so that the tensile stress of the first stress film 102 is greater than the tensile stress of the second stress film 104. The tensile stress of the second stress film 104 is smaller than the tensile stress of the first stress film 102. The stress layer 100 includes an insulator, for example, silicon nitride. The interlayer insulating film 26 contains silicon dioxide (SiO₂), for example.

Since the first stress film 102 is provided in the first region A, a tensile stress greater than that in the second region B is applied to the channel portion 28a of the transistor Tr1. Therefore, the lattice spacing of the silicon single crystal in the channel portion 28a is larger than that in the channel portion 28b. This causes electron mobility in the channel portion 28a to increase. Since the transistor Tr1 provided in the first region A is an N-channel MOSFET, carriers are electrons. Therefore, the electron mobility in the channel portion 28a increases, so that the capability of the transistor Tr1 is enhanced.

Since the second stress film 104 is provided in the second region B, the tensile stress applied to the channel portion 28b of the transistor Tr2 is smaller than the tensile stress applied to the channel portion 28a of the first region A. As the lattice spacing of the silicon single crystal in the channel portion 28b becomes smaller, the hole mobility becomes lower, but the tensile stress of the second stress film 104 provided in the second region B is lower than the tensile stress of the first stress film 102 provided in the first region A. Therefore, decrease in hole mobility in the channel portion 28b is restricted. Since the transistor Tr2 provided in the second region B is a P-channel MOSFET, carriers are holes. Therefore, decrease in hole mobility in the channel portion 28b is restricted, so that deterioration in the capability of the transistor Tr2 is restrained.

As shown in FIG. 1B, a third region C and a fourth region D are provided on the semiconductor substrate 10 in the second peripheral region. The semiconductor substrate 10 in the third region C is doped with, for example, boron (B) to be provided with a P-type conductivity type P-well. The semiconductor substrate 10 in the fourth region D is doped with, for example, phosphorus (P) to be provided with an N-type conductivity type N-well. The third region C is provided with transistors Tr3 and Tr4. The fourth region D is provided with transistors Tr5 and Tr6. The transistors Tr3 and Tr4 are, for example, N-type conductivity type N-channel MOSFETs to be used in a peripheral circuit. The transistors Tr5 and Tr6 are, for example, P-type conductivity type P-channel MOSFETs to be used in a peripheral circuit. The transistors Tr3, Tr4, Tr5, and Tr6 constitute, for example, a COM S circuit. The second peripheral region is a region where a peripheral circuit is provided. Examples of the peripheral circuit include control circuits such as a decoder and a driver, and an input/output circuit.

Each of the transistors Tr3 and Tr4 includes a third gate electrode 30 and sources/drains 34 arranged on the semiconductor substrate 10 on both sides of the third gate electrode 30. The semiconductor substrate 10 below the third gate electrode 30 serves as channel portions 28c and 28d. A gate insulating film 14 is provided between the third gate electrode 30 and the semiconductor substrate 10. A gate upper insulating film 15 is provided on the third gate electrode 30. A first sidewall portion 16 and a second sidewall portion 18 are provided on the sidewalls of the third gate electrode 30 and the gate upper insulating film 15.

The third gate electrode 30 includes a conductive material, and includes, for example, a laminated film of tungsten and polysilicon. The source/drain 34 includes a doped portion 34a, an LDD portion 34c, and a silicide portion 34d. The doped portion 34a and the LDD portion 34c are doped with impurities such as arsenic or phosphorus. The LDD portion 34c is a doped region which is formed shallowly up to a gate end near the surface of the semiconductor substrate 10, and serves as an extension portion of the source/drain 34. A short channel effect may be restricted by providing a halo implant region (not shown) so as to surround the LDD portion 34c. The silicide portion 34d includes, for example, titanium silicide (TiSi) or cobalt silicide (CoSi). The channel portions 28c and 28d are doped with impurities such as phosphorus, arsenic, or boron. The other configuration is the same as the configuration of the transistor Tr1 described above.

Each of the transistors Tr5 and Tr6 includes a fourth gate electrode 32 and sources/drains 36 arranged on both sides of the fourth gate electrode 32. A gate insulating film 14 is provided between the fourth gate electrode 32 and the semiconductor substrate 10. A gate upper insulating film 15 is provided on the fourth gate electrode 32. A first sidewall portion 16 and a second sidewall portion 18 are provided on the sidewalls of the fourth gate electrode 32 and the gate upper insulating film 15. A silicide portion 36d is provided on the source/drain 36.

The fourth gate electrode 32 includes a conductive material, and includes, for example, a laminated film of tungsten and polysilicon. The source/drain 36 includes a buried SiGe portion 36a, a doped portion 36b, an LDD portion 36c, and a silicide portion 36d. The buried SiGe portion 36a contains silicon germanium (SiGe). The buried SiGe portion 36a contains SiGe buried in a recess provided in the semiconductor substrate 10. The doped portion 36b is provided in the buried SiGe portion 36a, and is doped with, for example, impurities such as boron. The LDD portion 36c is a doped region in which impurities such as boron is introduced shallowly up to a gate end near the surface of the semiconductor substrate 10, and serves as an extension portion of the source/drain 36. The silicide portion 36d contains, for example, titanium silicide (TiSi) or cobalt silicide (CoSi). The other configuration is the same configuration as the transistors Tr4 and Tr5.

A first insulating film 24 and a stress layer 100 are provided above the transistors Tr3 and Tr4 and the transistors Tr5 and Tr6 and on the semiconductor substrate 10 so as to cover them. An interlayer insulating film 26 is provided on the stress layer 100 so as to cover it. The stress layer 100 includes a third stress film 106 and a fourth stress film 108. The third stress film 106 is provided in the third region C. The fourth stress film 108 is provided in the fourth region D. A damage is applied to the fourth stress film 108 as described later, so that the tensile stress of the fourth stress film 108 is smaller than the tensile stress of the first stress film 102. The stress layer 100 contains, for example, silicon nitride. The interlayer insulating film 26 contains, for example, silicon dioxide (SiO₂).

FIG. 1C is a vertically cross-sectional view showing a schematic configuration of the semiconductor device 1 in which the first region A, the second region B, the third region C, and the fourth region D are combined into one diagram, and isolations 60, contact plugs 62, and wirings 64 are further added. As shown in FIG. 1C, the stress layer 100 covers over the transistors Tr1, Tr2, Tr3, Tr4, Tr5, Tr6 and the isolations 60 in the regions A, B, C, and D. Further, the contact plugs 62 that penetrate the interlayer insulating film 26 and the stress layer 100 are connected to the respective sources/drains 20, 22, 34, and 36 of the transistors Tr1, Tr2, Tr3, Tr4, Tr5, and Tr6, respectively. The wirings 64 arranged in the interlayer insulating film 26 are connected to the contact plugs 62. The isolations 60 are regions for electrically separating adjacent transistors from each other, and contain, for example, an insulating material such as silicon dioxide. The contact plugs 62 and the wirings 64 include a conductive material such as tungsten.

Since the third stress film 106 is provided in the third region C, tensile stress is applied to the respective channel portions 28c and 28d of the transistors Tr3 and Tr4. Therefore, the lattice spacing of the silicon single crystal in the channel portions 28c and 28d increases. As a result, the electron mobility in the channel portions 28c and 28d increases. Since the transistors Tr3 and Tr4 provided in the third region C are N-channel MOSFETs, the carriers are electrons. Therefore, the electron mobility in the channel portions 28c and 28d increases, so that the capability of the transistors Tr3 and Tr4 is improved.

Since the fourth stress film 108 is provided in the fourth region D, the tensile stress applied to the channel portions 28e and 28f of the transistors Tr5 and Tr6 is smaller than the tensile stress applied to the channel portions 28c and 28d of the third region C. Further, the sources/drains 36 arranged on both sides of the channel portions 28e and 28f contain SiGe. The lattice spacing of SiGe is larger than the lattice spacing of silicon. Therefore, compressive stress is applied to the channel portions 28e and 28f sandwiched between the sources/drains 36 including the SiGe portions 36a. Therefore, the lattice spacing of the silicon single crystal in the channel portions 28e and 28f decreases. As a result, the hole mobility in the channel portions 28e and 28f increases. Since the transistors Tr5 and Tr6 provided in the fourth region D are P-channel MOSFETs, the carriers are holes. Therefore, the hole mobility in the channel portions 28e and 28f increases, so that the capability of the transistors Tr5 and Tr6 is improved. Further, since the tensile stress applied to the channel portions 28e and 28f is reduced by the fourth stress film 108 to which a damage has been applied, deterioration in the capability of the transistors Tr5 and Tr6 is restrained.

As described above, in the semiconductor device 1 according to the embodiment, the capabilities of the transistors Tr1, Tr3, Tr4, Tr5, and Tr6 are improved, and the deterioration in the capability of the transistor Tr2 is restrained. Therefore, it is possible to improve the overall capabilities of the electronic circuit including the transistors Tr1 and Tr2 in the first peripheral region and the electronic circuit including the transistors Tr3 to Tr6 in the second peripheral region.

Next, a method for manufacturing the semiconductor device 1 according to the embodiment will be described.

First, as shown in FIGS. 2A and 2Bb, the gate insulating film 14, the first gate electrodes 12, 13, 30, 32, and the gate upper insulating film 15 are formed on the semiconductor substrate 10. The gate insulating film 14, the first gate electrodes 12, 13, 30, 32, and the gate upper insulating film 15 are formed by sequentially forming films of hafnium oxide, polysilicon, tungsten, and silicon nitride on the semiconductor substrate 10, and sequentially etching these films using, for example, a publicly known lithography technique. The films of hafnium oxide, polysilicon, tungsten, and silicon nitride are formed using, for example, Chemical Vapor Deposition (CVD). Further, for the etching, for example, anisotropic dry etching is used.

Next, a film of silicon nitride is formed using CV D so as to cover the semiconductor substrate 10, the gate insulating film 14, the first gate electrodes 12, 13, 30, 32, and the upper portion of the gate upper insulating film 15, and then etch back using anisotropic dry etching is performed on the thus-formed silicon nitride film. As a result, first sidewall portions 16 are formed on the side surfaces of the gate insulating film 14, the first gate electrodes 12, 13, 30, 32, and the gate upper insulating film 15. Next, a photoresist is formed using a publicly known lithography technique, and ion implant is performed on the semiconductor substrate 10 in the first region A, the second region B, the third region C, and the fourth region D to form the LDD portions 20c, 22c, 34c, and 36c. For example, arsenic or phosphorus is implanted into the LDD portions 20c and 34c. For example, boron is implanted into the LDD portions 22c and 36c. Furthermore, a halo implant region may be further formed so as to surround the LDD portions 20c, 22c, 34c, and 36c. In the N-channel MOSFET, a halo implant region is formed, for example, by ion-implanting boron into the LDD portions 20c and 34c. Furthermore, in the P-channel MOSFET, a halo implant region is formed, for example, by ion-implanting arsenic or phosphorus into the LDD portions 22c and 36c.

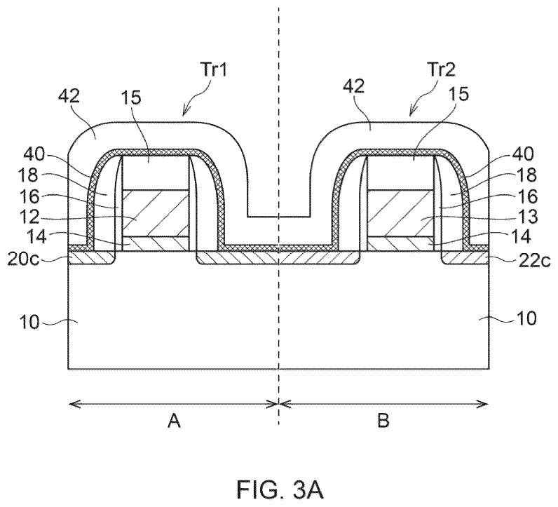

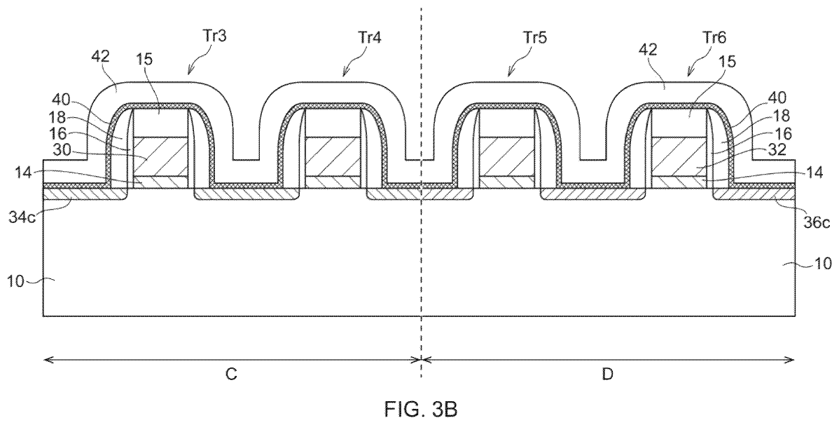

Next, as shown in FIGS. 3A and 3B, a silicon nitride film is formed to cover the entire surface by using CVD or Atomic Layer Deposition (ALD), and then etch back using anisotropic dry etching is performed on the thus-formed silicon nitride film. As a result, a second sidewall portion 18 is formed on the side surface of the first sidewall portion 16. Subsequently, a second insulating film 40 and a third insulating film 42 are formed to cover the entire surface by using CVD. The second insulating film 40 contains, for example, silicon dioxide, and the third insulating film 42 contains, for example, silicon nitride.

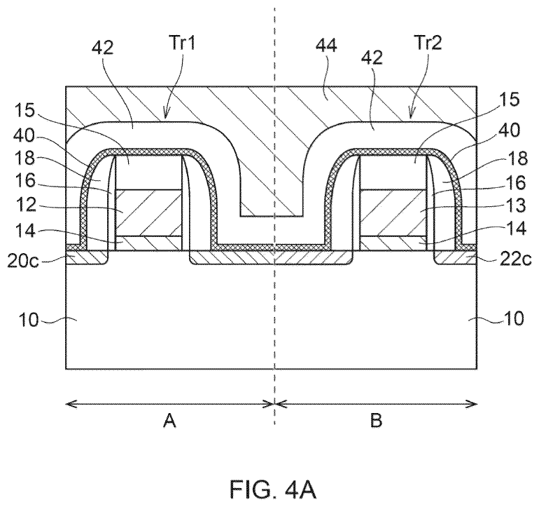

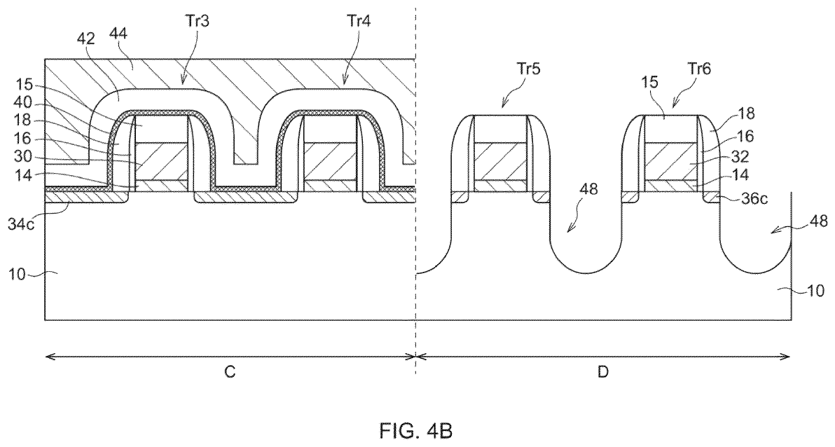

Next, as shown in FIGS. 4A and 4B, a photoresist 44 is formed to cover the first region A, the second region B, and the third region C and cause the fourth region D to be exposed therefrom. The photoresist 44 is formed using a publicly known lithography technique. Next, for example, isotropic dry etching is performed on the fourth region D with the photoresist 44 as a mask to selectively remove the third insulating film 42 and the second insulating film 40 in the fourth region D. As a result, the upper surface of the semiconductor substrate 10 between the fourth gate electrodes 32 is exposed. Next, anisotropic dry etching is performed on the semiconductor substrate 10 with the gate upper insulating film 15 and the second sidewall portions 18 as masks to form recesses 48 on the semiconductor substrate 10 in regions which are not covered by the gate upper insulating film 15 and the second sidewall portions 18. This anisotropic dry etching is performed under a condition that the etching rate of silicon is higher than the etching rate of silicon nitride contained in the gate upper insulating film 15 and the second sidewall portion 18. The recesses 48 are formed in the source/drain regions of the above-mentioned transistors Tr5 and Tr6.

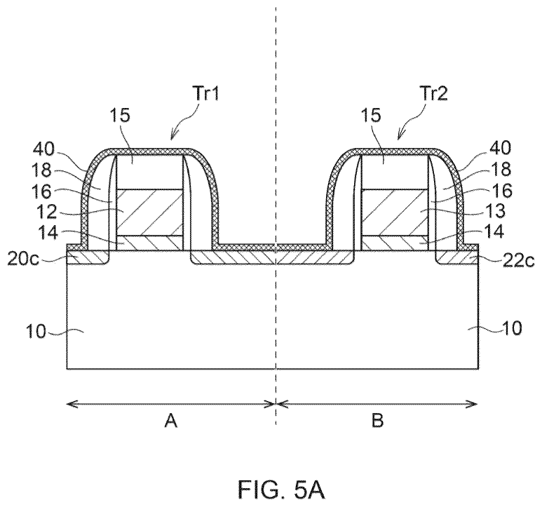

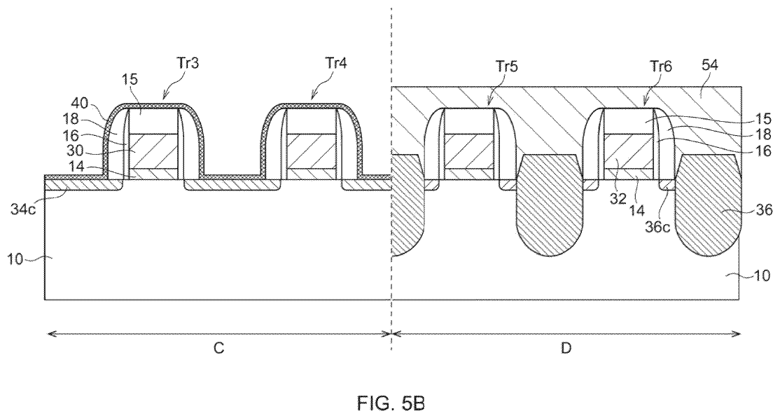

Next, as shown in FIGS. 5A and 5B, SiGe is epitaxially grown on the silicon surfaces within the recesses 48 to bury SiGe in the recesses 48 to form a buried SiGe portion 36a. SiGe becomes a single crystal. In the epitaxial growth of SiGe, SiGe is doped with boron by adding boron to source gas. By epitaxial growth of SiGe, the SiGe portions 36a are formed such that the upper surfaces thereof rise to be higher than the upper surface of the semiconductor substrate 10. Next, a photoresist 54 is formed in the fourth region D using a publicly known lithography technique, and isotropic dry etching is performed on the third insulating films 42 in the first region A, the second region B, and the third region C with the photoresist 54 as a mask. As a result, the third insulating films 42 in the first region A, the second region B, and the third region Cs are selectively removed. This isotropic dry etching is performed under a condition that the etching rate of silicon nitride contained in the third insulating film 42 is higher than the etching rate of silicon dioxide contained in the second insulating film 40.

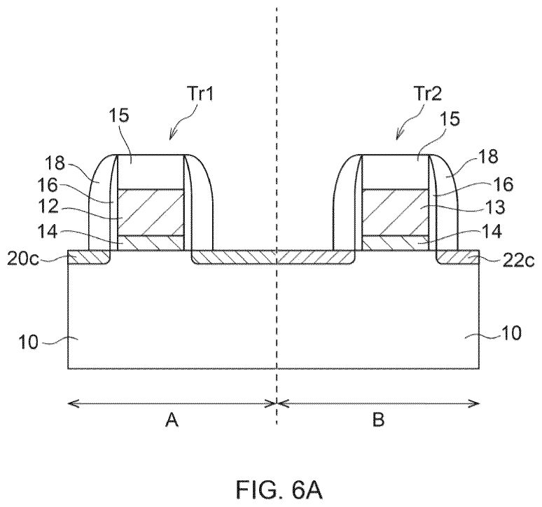

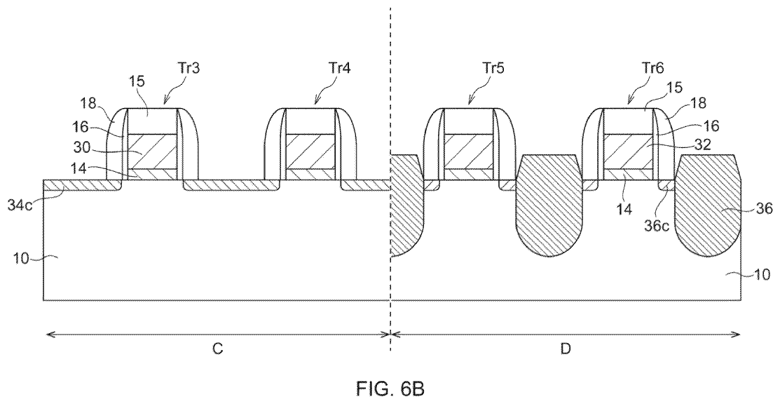

Next, as shown in FIGS. 6A and 6B, the photoresist 54 is removed, and then the second insulating films 40 in the first region A, the second region B, and the third region C are removed using buffered hydrofluoric acid (BHF). Since BHF has high etching selectivity, the gate upper insulating film 15, the second sidewall portions 18, and the buried SiGe portions 36a in the fourth region D are not etched by BHF, and the second insulating film 40 is selectively removed.

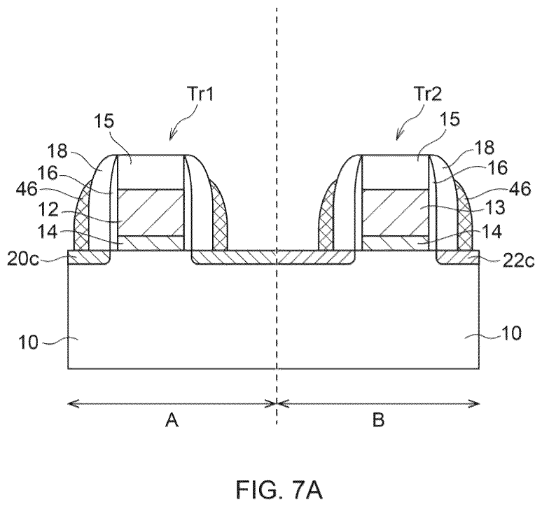

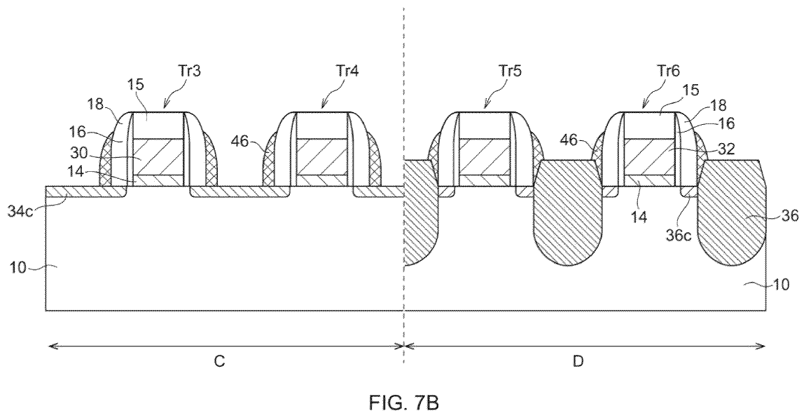

Next, as shown in FIGS. 7A and 7B, a silicon oxide film is formed using CVD, and then etch back using anisotropic dry etching is performed to form the third sidewall portions 46 on the sidewalls of the second sidewall portions 18. This anisotropic dry etching is performed under a condition that the etching rates of silicon nitride, silicon, and SiGe are sufficiently lower than the etching rate of silicon dioxide.

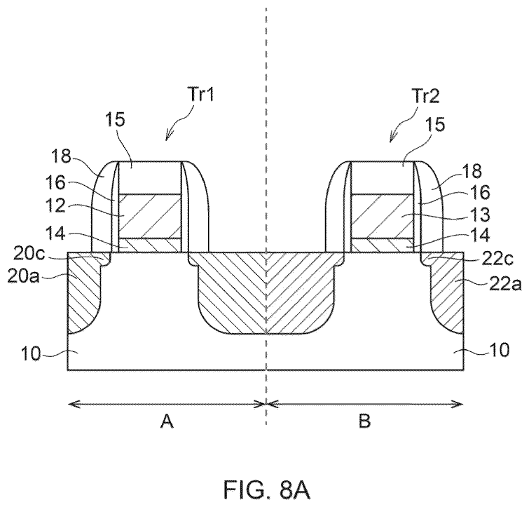

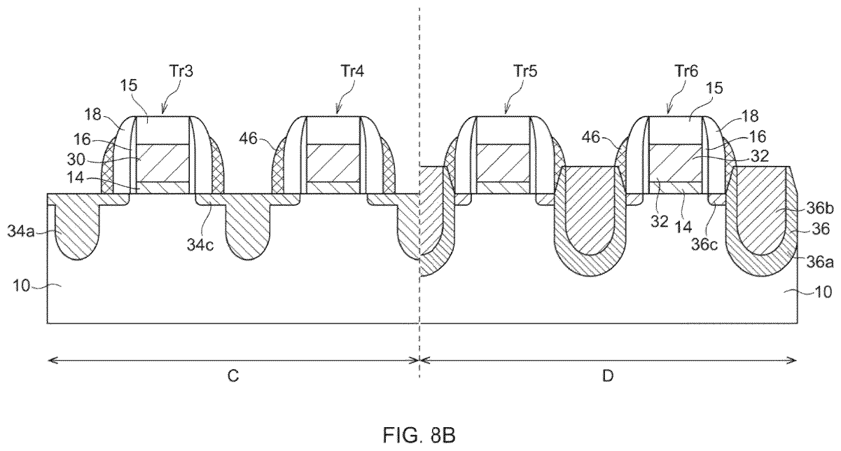

Next, as shown in FIGS. 8A and 8B, a photoresist is formed in the third region C and the fourth region D using a publicly known lithography technique, and wet etching using BHF is performed on the first region A and the second region B with the above photoresist as a mask to remove the third sidewall portions 46 in the first region A and the second region B. Next, after removing the photoresist, arsenic ions are implanted into the semiconductor substrate 10 in the first region A and the third region C, whereby the doped portions 20a and the doped portions 34a are formed. Further, boron ions are implanted into the semiconductor substrate 10 in the second region B and the buried SiGe portions 36a in the fourth region D. As a result, the doped portions 22a and the doped portions 36b are formed. In these ion implantations, a photoresist is formed in any region or a plurality of regions of the first region A, the second region B, the third region C and the fourth region D using a publicly known lithography technique, whereby specific chemical species can be implanted into selected regions. Since the implanted ions are offset by the third sidewall portions 46, the doped portions 34a are formed slightly inside the LDD portions 34c, and the doped portions 36b are formed slightly inside the buried SiGe portions 36a.

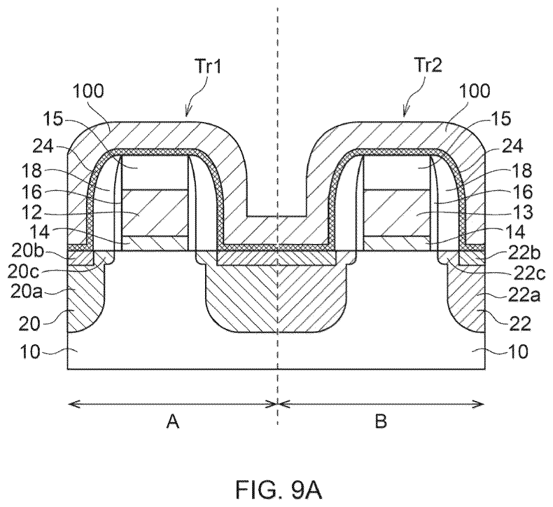

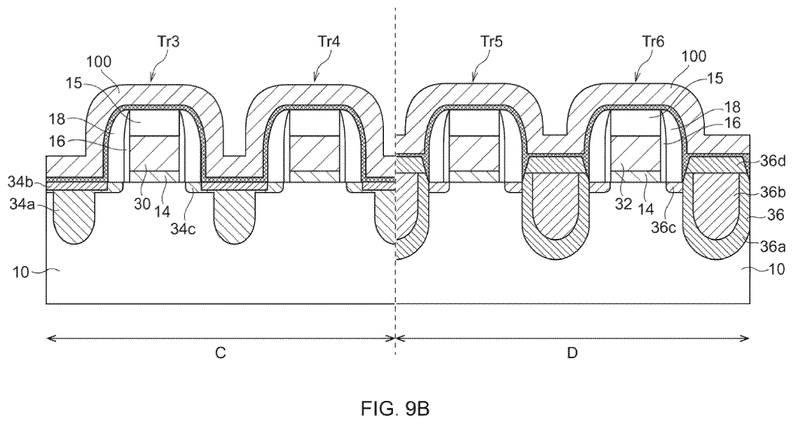

Next, as shown in FIGS. 9A and 9B, wet etching using BHF is performed to selectively remove the third sidewall portions 46 in the third region C and the fourth region D. Next, silicide portions 20b, 22b, 34d, and 36d are formed at upper portions of the sources/drains 20, 22, 34, and 36, respectively. The silicide portions 20b, 22b, 34d, and 36d are formed, for example, by using a salicide technique (salicide, self-aligned silicide) described below.

Formation of the silicide portions 20b, 22b, 34d, and 36d by the salicide technique is performed by the following steps. First, metal such as nickel (Ni)-platinum (Pt), titanium (Ti), or cobalt (Co) is formed so as to cover the gate upper insulating film 15, the second sidewall portions 18, and the surface of the semiconductor substrate 10 in the first region A, the second region B, the third region C, and the fourth region D, and then sintering is performed to react silicon of the semiconductor substrate 10 and the buried SiGe portions 36a with the metal, thereby forming metal silicide such as nickel platinum silicide (NiPtSi), nickel silicide (NiSi), or cobalt silicide (CoSi). The metal silicide is formed near the semiconductor substrate 10 or the buried SiGe portions 36a, and the rest remains as unreacted surplus metal. Next, the surplus metal is removed with ammonia peroxide (ammonia/hydrogen peroxide) to form the silicide portions 20b, 22b, 34d, and 36d. The silicide portions 20b, 22b, 34d, and 36d can be selectively formed at upper portions of the sources/drains 20, 22, 34, and 36 by the salicide technique.

Next, the first insulating film 24 and the stress layer 100 are formed on the semiconductor substrate 10 having the above configuration thereon by using CVD. The first insulating film 24 contains an insulating material, for example silicon dioxide. The stress layer 100 contains an insulating material, for example silicon nitride. Silicon nitride is known as a material having tensile stress. Through the above steps, the configuration shown in FIGS. 9A and 9B is implemented.

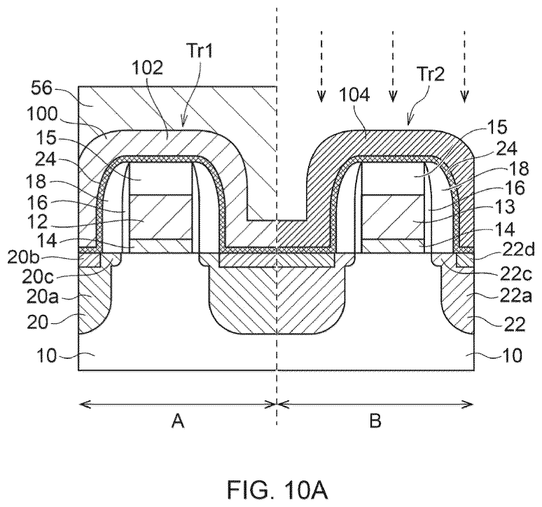

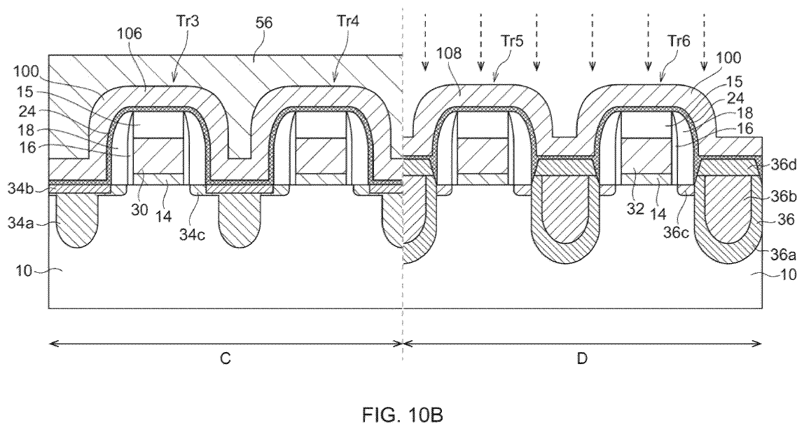

Next, as shown in FIGS. 10A and 10B, a photoresist 56 is formed by using a publicly known lithography technique so as to cover the first region A and the third region C and cause the second region B and the fourth region D to be exposed therefrom. Note that the semiconductor device 1 has a memory cell region, and thus the photoresist 56 is formed so as to cover this memory cell region as well. Next, ion implantation is performed on the stress layers 100 in the second region B and the fourth region D by using the photoresist 56 as a mask. In this ion implantation, silicon or germanium is implanted. Further, this ion implantation is performed using an implantation energy that does not allow the chemical species to be implanted to penetrate through the stress layer 100. Silicon or germanium is ion-implanted under conditions of, for example, an implantation energy of about 10 keV to 30 keV and an implantation amount of about 1.0×10¹⁵ to 1.0×10¹⁶ atoms/cm². In this ion implantation, carbon (C) or nitrogen (N) may be implanted. Note that even when these chemical species penetrate through the stress layer 100 and are implanted into the semiconductor substrate 10, etc., the change in device characteristics is almost negligible because the second region B and the fourth region D are regions where P-channel MOSFETs are formed.

Here, a hard mask may be used instead of the photoresist 56. When a hard mask is used, for example, after a carbon film is formed, a resist is formed using a publicly known lithography technique, and then the carbon film is etched to form a hard mask covering the upper side of the first region A, the upper side of the third region C, and the upper side of the memory cell region, and chemical species such as silicon or germanium are ion-implanted using this hard mask as a mask.

This ion implantation applies a damage to the stress layer 100 in the second region B and the fourth region D to relax the tensile stress of silicon nitride contained in the stress layer 100. This ion implantation causes the stress layer 100 to include the first stress film 102 and the third stress film 106 which are not damaged, and the second stress film 104 and the fourth stress film 108 which have been damaged. The tensile stress of the stress layer 100 in a region where the first stress film 102 and the third stress film 106, that is, a non-damaged silicon nitride film is provided is greater than the tensile stress of the stress layer 100 in a region where the second stress film 104 and the fourth stress film 108, that is, a damaged silicon nitride film is provided.

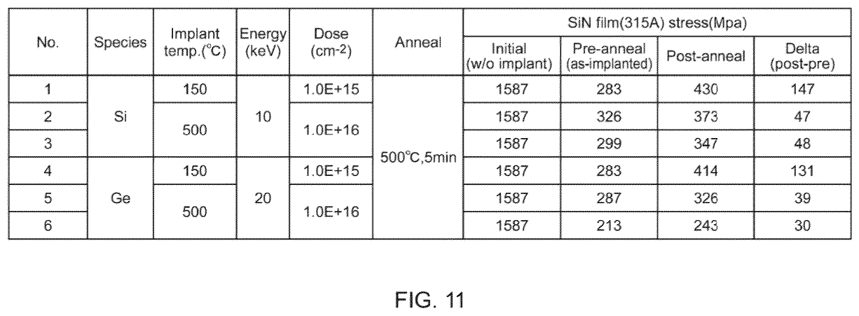

FIG. 11 is a table showing experimental results showing changes in tensile stress when ions of silicon or germanium are implanted into silicon nitride. In Experiments Nos. 1 to 3, silicon ions were implanted under a condition of an implantation energy of 10 keV, and in Experiments Nos. 4 to 6, germanium ions were implanted under a condition of an implantation energy of 20 keV. Further, in Experiments Nos. 1 and 4, ions were implanted under a condition of an ion implantation temperature of 150° C. and an implantation amount of 1.0×10¹⁵ atms/cm². In Experiments Nos. 2, 3, 5, and 6, ions were implanted under a condition of an ion implantation temperature of 500° C. and an implantation amount of 1.0×10¹⁶ atms/cm². The film thickness of silicon nitride was 315 angstroms, and the heat treatment was performed at 500° C. for 5 minutes in an inert gas atmosphere. The tensile stress of silicon nitride which had not been subjected to ion-implantation was 1587 M Pa. In experiments Nos. 1 to 6, the tensile stress was 213 M Pa to 430 M Pa. From the above, it has been shown that when silicon, germanium, or the like is ion-implanted into silicon nitride, the tensile stress thereof is significantly reduced.

Next, as shown in FIGS. 1A and 1B, after the photoresist 56 is removed, the interlayer insulating film 26 is formed on the semiconductor substrate 10 provided with the above configuration by using CVD. The interlayer insulating film 26 contains an insulating material, for example, silicon dioxide. Through the above steps, the semiconductor device 1 according to the embodiment was formed.

Furthermore, by using publicly known lithography technique and anisotropic dry etching, contact holes are formed to penetrate the interlayer insulating film 26 and the stress layer 100 and reach the upper surfaces of the sources/drains 20, 22, 34, and 36 from the upper surface of the interlayer insulating film 26. Thereafter, for example, tungsten is buried at least in the contact holes, for example, by using CV D, and polished using chemical mechanical polishing (CM P) until the tungsten on the upper surface of the interlayer insulating film 26 is removed, thereby forming the contact plugs 62. Furthermore, the wirings 64 can be formed by forming, for example, a film of tungsten using CV D and processing the tungsten using the publicly known lithography technique and anisotropic dry etching. Through the above steps, the semiconductor device 1 shown in FIG. 1C was formed.

As described above, the semiconductor device 1 according to the embodiment has been described by illustrating DRAM as an example, but this is just one example and is not intended to be limited to DRAM. The semiconductor device 1 may be applied to memory devices other than DRAM, for example, memory devices such as a static random access memory (SRAM), a flash memory, an erasable programmable read only memory (EPROM), a magnetoresistive random access memory (M RAM), a phase-change memory and the like. Further, the semiconductor device 1 may be applied to devices other than memories, for example, logic ICs such as a microprocessor and an application specific integrated circuit (ASIC).

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a substrate;
a first region on the substrate;
a second region on the substrate;
at least one first transistor provided in the first region;
at least one second transistor provided in the second region;
a first stress film covering over the first transistor; and
a second stress film covering over the second transistor;
wherein stress of the first stress film is different from stress of the second stress film.

2. The apparatus of claim 1, wherein the first stress film and the second stress film include silicon nitride, and tensile stress of the first stress film is greater than tensile stress of the second stress film.

3. The apparatus of claim 1, wherein the first stress film is a non-damaged film and the second stress film is a damaged film.

4. The apparatus of claim 1, wherein the second stress film includes a doped Si or a doped Ge and the first stress film does not include either a doped Si or a doped Ge.

5. The apparatus of claim 1, wherein the first stress film and the second stress film are included in the same layer.

6. The apparatus of claim 1, wherein both the first transistor and the second transistor are MOSFETs.

7. The apparatus of claim 6, wherein the first transistor is first conductive type and the second transistor is second conductive type.

8. The apparatus of claim 7, wherein the first transistor is N-channel MOSFET and the second transistor is P-channel MOSFET.

9. The apparatus of claim 8, wherein the second transistor includes a source and a drain each including SiGe embedded in the substrate.

10. An apparatus comprising:
a substrate;
a first region including at least one N-channel MOSFET on the substrate;
a second region including at least one P-channel MOSFET on the substrate;
a first stress film covering over the N-channel MOSFET in the first region; and
a second stress film covering over the P-channel MOSFET in the second region;
wherein the second stress film is a damaged film.

11. The apparatus of claim 10, wherein the first stress film and the second stress film include silicon nitride.

12. The apparatus of claim 10, wherein the second stress film is doped with Si.

13. The apparatus of claim 10, wherein the second stress film is doped with Ge.

14. The apparatus of claim 10, wherein tensile stress of the first stress film is greater than that of the second stress film.

15. The apparatus of claim 10, wherein the first stress film and the second stress film are included in the same layer.

16. The apparatus of claim 10, wherein the P-channel MOSFET includes a source and a drain including SiGe embedded in the substrate.

17. A method comprising:
forming a first region and a second region on a substrate;
forming at least one N-channel MOSFET in the first region;
forming at least one P-channel MOSFET in the second region;
depositing a silicon nitride film over the first region and the second region to cover each of the N-channel MOSFET and the P-channel MOSFET;
forming a mask covering at least a part of the first region and exposing the second region;
performing an ion implantation using the mask to dope chemical species into the silicon nitride film in the second region.

18. The method of claim 17, wherein the chemical species contains silicon.

19. The method of claim 17, wherein the chemical species contains germanium.

20. The method of claim 17, wherein the silicon nitride film is formed using Chemical Vapor Deposition.
